(19) United States
(12) Patent Application Publication
(10) Pub. No.: US 2008/0216886 A1
(43) Pub. Date: Sep. 11, 2008

(54) Solar Cell Module

(76) Inventor: Tadashi Iwakura, Tochigi-ken (JP)

Correspondence Address: ARENT FOX LLP, 1050 CONNECTICUT AVENUE, N.W., SUITE 400, WASHINGTON, DC, 20036, US

(21) Appl. No.: 11/922,989

(22) PCT Filed: Jun. 29, 2006
(86) PCT No.: PCT/JP2006/312969

§ 371 Date: Dec. 28, 2007

(30) Foreign Application Priority Data
Jul. 1, 2005 (JP) 2005-193584

(51) Int. Cl. H01L 31/04

(52) U.S. Cl. 136/244

(57) ABSTRACT

Disclosed is a solar cell module comprising ten solar cells. The widths W1 of the solar cells arranged on the ends and the solar cells respectively arranged next to the solar cells are set 10-25% (1.1-1.25 times) longer than the widths W2 of the other solar cells. Consequently, the cell areas of the solar cells are larger than the cell areas of the other solar cells.

### TECHNICAL FIELD

The present invention relates to a solar cell module comprising a cell unit made up of a plurality of solar cells disposed on a single substrate.

### BACKGROUND ART

Chalcopyrite solar cells are solar cells having a chalcopyrite compound (hereinafter referred to as “CIGS”) represented as Cu(InGa)Se as a light absorption layer. Much attention has been paid to chalcopyrite solar cells because they have many advantages, e.g., they have a high energy conversion efficiency, are almost free of light-induced degradation due to aging, are of excellent radiation resistance, have a wide light absorption wavelength range, and have a large light absorption coefficient.

As shown in FIG. 5, a plurality of chalcopyrite solar cells 1 of the type described are monolithically disposed on a single glass substrate 2, providing a cell unit 3. Each of the chalcopyrite solar cells 1 comprises, for example, a first electrode layer 4 made of Mo, a light absorption layer 5 made of CIGS, a buffer layer 6 made of CdS, ZnO, or InS, and a transparent second electrode layer 7 made of ZnO/Al, which are successively deposited in the order named on the glass substrate 2.

The solar cells 1 are fabricated when they are divided by three scribing processes at the time the above layers are formed. Specifically, the first scribing process is performed after the first electrode layer 4 of Mo is formed. The second scribing process is performed after the buffer layer 6 is formed. The third scribing process is performed after the transparent second electrode layer 7 is formed. The solar cells 1 have their transverse dimensions determined by setting intervals at which the scribing processes are to be carried out.

As shown in FIG. 6, the cell unit 3 is sealed in a casing 8 by a resin material, not shown, thereby providing a solar cell module 9. A plurality of cell units 3 may be housed in the casing 8.

The solar cell module 9 is capable of generating a high voltage ranging from several tens to several hundreds V when the intervals at which to scribe the cell unit 3 is subjected to scribing are adjusted and the number of solar cells 1 that are connected in series is changed (see, for example, Patent document 1). The solar cells 1 are divided at equal intervals based on data programmed in the scriber apparatus, as disclosed in Patent document 2. As a result, as shown in FIG. 6, the solar cells 1 have identical transverse dimensions.

Patent document 1: Japanese Laid-Open Patent Publication No. 11-312815

Patent document 2: Japanese Laid-Open Patent Publication No. 2004-115356

### DISCLOSURE OF THE INVENTION

If solar cell modules are large in size, then it is often observed that the power generating capability of the solar cell modules is smaller than that estimated from the area of the solar cells.

The inventor of the present invention has looked into the above problem and found that the amounts of generated currents of those solar cells which are positioned at the ends of the solar cell module 9 are smaller than the amounts of generated currents of the other solar cells. In other words, the power generating capability of a solar cell module depends greatly upon the amounts of generated currents of those solar cells which are positioned at the ends of the solar cell module. If the amounts of generated currents of these solar cells are small, then the power generating capability of the overall solar cell module is not sufficiently large even though the amounts of generated currents of the other solar cells are large.

It may be proposed to increase the amounts of generated currents of those solar cells which are positioned at the ends of the solar cell module in order to increase the power generating capability of the solar cell module. To realize the proposal, variations of the film thicknesses and compositions of a precursor which will be processed into the light absorption layer and the transparent second electrode layer may be reduced when solar cells are fabricated, because different film thicknesses and compositions of those layers adversely affect the amount of generated currents.

It may also be proposed to reduce variations of a temperature distribution in a seleniding furnace during a process of seleniding the precursor for producing the light absorption layer, or to reduce the difference between the flowing speeds, respectively at central and end portions of the glass substrate, of a solution used in a chemical bath bonding (CBD) process for forming the buffer layer.

However, if the solar cell module is large in size, then since the glass substrate is also large in size, it is difficult to reduce the variations of the film thicknesses and compositions of the precursor and the second electrode layer by sputtering, to reduce the variations of the temperature distribution in the seleniding furnace, and to reduce the difference between the flowing speeds, respectively at the central and end portions of the glass-substrate, of the solution used in the CBD process.

The inventor has made various intensive studies based on the above findings, and has accomplished the present invention.

It is a general object of the present invention to provide a solar cell module comprising solar cells whose amounts of generated currents are substantially uniform.

A major object of the present invention is to provide a solar cell module which is large in size and yet exhibits an excellent power generating capability.

According to an embodiment of the present invention, there is provided a solar cell module including at least one cell unit comprising a plurality of solar cells on a single substrate, each of the solar cells comprising a first electrode layer, a p-type light absorption layer, an n-type buffer layer, and a transparent second electrode layer which are successively disposed in the order named on the substrate in a direction away from the substrate, the solar cells being electrically connected in series to each other, wherein the solar cells have a plurality of cell areas.

According to the present invention, therefore, there are solar cells having different cell areas. The different cell areas make it possible to substantially uniformize the amounts of generated currents of the solar cells.

According to the present invention, those solar cells which would have smaller amounts of generated currents if electricity were generated by a solar cell module made up of solar cells having identical areas, are constructed as solar cells having larger cell areas to increase amounts of generated currents thereof, so that the amounts of generated currents of the solar cells are made substantially uniform. As a result, the conversion efficiency of the overall solar cell module is increased. The power generating capability of the overall solar cell module is thus increased. Stated otherwise, there is provided a solar cell module of excellent power generating characteristics.

If all the solar cells have identical cell areas, then those solar cells that are positioned at the ends of the solar cell module have smaller amounts of generated currents. Therefore, those solar cells having larger cell areas should preferably be disposed at the ends thereby to increase the amounts of generated currents of the solar cells at the ends. Stated otherwise, the solar cells disposed at the ends of the solar cell module should preferably be of larger cell areas than the solar cells disposed in a central portion of the solar cell module.

If the total number of the solar cells is even, then the central portion is made up of two solar cells. For example, if the cell unit comprises ten solar cells, then the central portion is made up of two solar cells, i.e., fifth and sixth solar cells counted from the left end.

The solar cells may have identical longitudinal dimensions and different transverse dimensions, thereby providing the different cell areas. The “longitudinal” refers to a direction in which the solar cells have a larger dimension as viewed from above, and the “transverse” refers to a direction perpendicular to the longitudinal direction.

### BRIEF DESCRIPTION OF THE DRAWINGS

FIG. 1 is a schematic plan view of a solar cell module according to an embodiment of the present invention;

FIG. 2 is an enlarged fragmentary transverse cross-sectional view of a cell unit of the solar cell module shown in FIG. 1;

FIG. 3 is a table showing the relationship between the ratio of a transverse dimension W1 to a transverse dimension W2 of the solar cells and the conversion efficiency thereof;

FIG. 4 is a schematic plan view of a solar cell module according to another embodiment of the present invention;

FIG. 5 is an enlarged fragmentary transverse cross-sectional view of a cell unit made up of a plurality of solar cells monolithically disposed on a single substrate; and

FIG. 6 is a schematic plan view of a solar cell module of the background art.

### BEST MODE FOR CARRYING OUT THE INVENTION

Solar cell modules according to preferred embodiments of the present invention will be described in detail below with reference to the accompanying drawings.

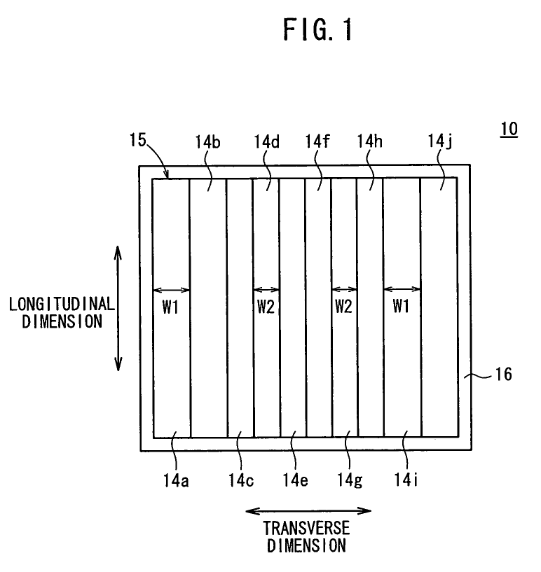

FIG. 1 is a schematic plan view of a solar cell module according to an embodiment of the present invention. The solar cell module 10 comprises a cell unit 15 made up of an array of ten adjacent solar cells 14a through 10f and housed in a casing 16. The casing 16 is filled with a molded mass of resin, not shown, protecting the solar cells 14a through 14j.

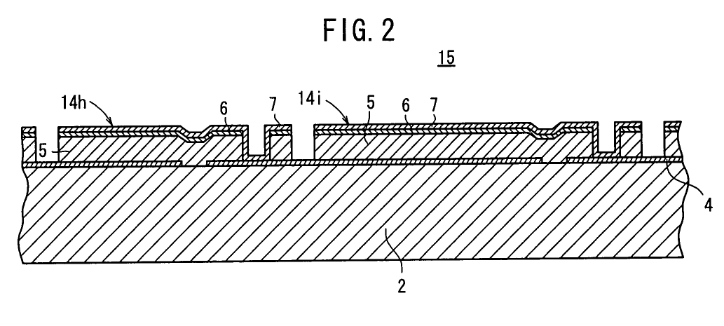

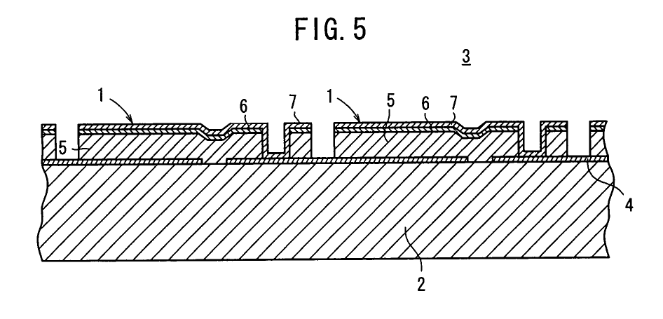

FIG. 2 shows the solar cells 14h, 14i in enlarged fragmentary transverse cross section. The transverse structure of the cell unit 15 is substantially the same as the cell unit 3 shown in FIG. 5. Specifically, the cell unit 15 has the solar cells 14a through 14j monolithically disposed on a single glass substrate 2. Each of the solar cells 14a through 14j comprises, for example, a first electrode layer 4 made of Mo, a light absorption layer 5 made of CIGS, a buffer layer 6 made of CdS, ZnO, or InS, and a transparent second electrode layer 7 made of ZnO/Al, which are successively deposited in the order named on the glass substrate 2.

As shown in FIGS. 1 and 2, each of the solar cells 14a, 14j that are positioned at the opposite ends of the cell unit 15 and the solar cells 14b, 14i that are positioned adjacent to respective solar cells 14a, 14j has a transverse dimension W1 greater than the transverse dimension W2 of each of the remaining solar cells 14c through 14h. Specifically, the transverse dimension W1 is about 10% to 25% greater than the transverse dimension W2, or stated otherwise, the solar cells 14a, 14b, 14j, 14i are about 10% to 25% wider than the solar cells 14c through 14h.

When light such as sunlight or the like is applied to the solar cell module 10, pairs of electrons and holes are produced in the light absorption layers 5 of the solar cells 14a through 14j. In the interfacial junction between the light absorption layer 5 of CIGS which is a p-type semiconductor and the second electrode layer 7 which is an n-type semiconductor, the electrons are attracted to the interface of the second electrode layer 7 (n-type) and the holes are attracted to the interface of the light absorption layer 5 (p-type), thereby producing an electromotive force between the light absorption layer 5 and the second electrode layer 7. The electric energy generated by the electromotive force is extracted as a current from a first electrode, not shown, that is electrically connected to the first electrode layer 4 of the solar cell 14a and a second electrode, not shown, that is electrically connected to the second electrode layer 7 of the solar cell 14j.

Since the solar cells 14a through 14j are connected in series to each other, the current flows, for example, from the solar cell 14a to the solar cell 14j. The electromotive force produced by the cell unit 15 is represented by the sum of electromotive forces produced by the respective solar cells 14a through 14j.

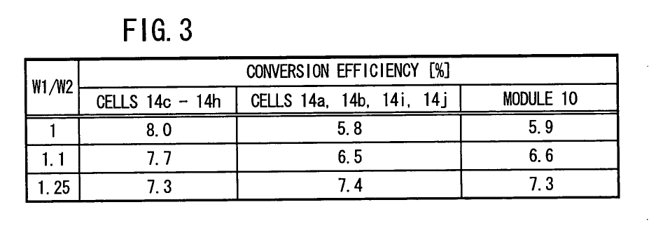

FIG. 3 shows different ratios of the transverse dimension W1 to the transverse dimension W2 and the conversion efficiencies of the end and adjacent solar cells 14a, 14b, 14i, 14j, the six intermediate solar cells 14c through 14h, and the entire solar cell module 10 at those different ratios.

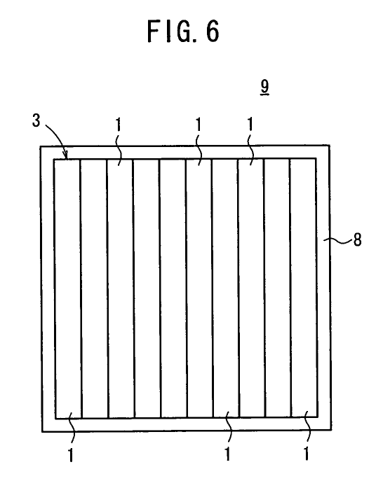

As can be seen from FIG. 3, if the transverse dimension W1 of the end and adjacent solar cells 14a, 14b, 14i, 14j is larger than the transverse dimension W2 of the other solar cells 14c through 14h, or stated otherwise if the area of the end and adjacent solar cells 14a, 14b, 14i, 14j is larger than the area of the intermediate solar cells 14c through 14h, then the amounts of generated currents of the end and adjacent solar cells 14a, 14b, 14i, 14j are substantially the same as the amounts of generated currents of the intermediate solar cells 14c through 14h. In other words, the amounts of generated currents of the end and adjacent solar cells 14a, 14b, 14i, 14j are prevented from being lowered, and hence the conversion efficiency of the overall solar cell module 10 is prevented from being lowered. As a result, the conversion efficiency of the overall solar cell module 10 is higher than the conversion efficiency of the solar cell module 9 (see FIG. 6) of the background art in which all the solar cells have of the same transverse dimension.

The reason for the foregoing is that since the transverse dimension W1 of the solar cells 14a, 14b, 14i, 14j is greater than the transverse dimension W2 of the remaining solar cells 14c through 14h and hence the cell area of the solar cells 14a, 14b, 14i, 14j is greater than the cell area of the remaining solar cells 14c through 14h, the amounts of generated currents of the solar cells 14a, 14b, 14i, 14j are large. The amounts of generated currents of the solar cells 14a, 14b, 14i, 14j are substantially the same as the amounts of generated currents of the solar cells 14c through 14h. As the amounts of generated currents of the solar cells 14a through 14f are substantially uniform, the conversion efficiency of the solar cell module 10 increases.

For making the transverse dimension of the solar cells 14a, 14b, 14i, 14j different, the intervals at which they are divided when they are scribed may be made different. Specifically, the data programmed in the scriber apparatus may be varied, for example.

Since the solar cells 14a, 14b, 14i, 14j which has the different transverse dimension can easily be fabricated, the manufacturing cost is not increased by making the transverse dimension of the solar cells 14a, 14b, 14i, 14j different.

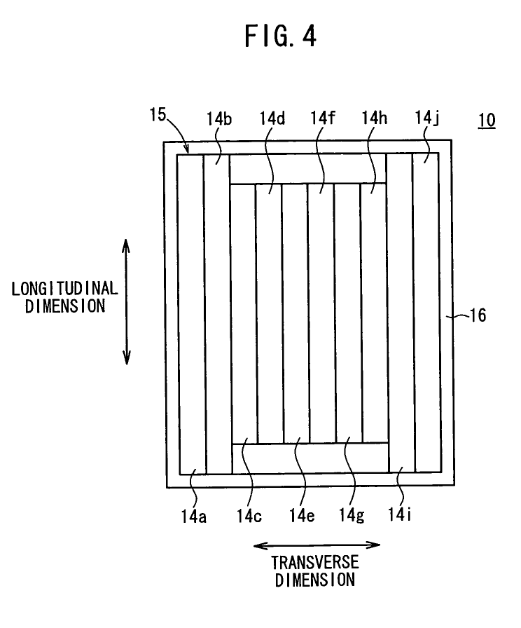

In the above embodiment, the area is made different by making the transverse dimension different. However, as shown in FIG. 4, the area may be made different by making the longitudinal dimension different.

At any rate, the number of solar cells used may be three or more, and is not particularly limited to ten. A plurality of cell units 15 may be housed in the casing 16 to provide a solar cell module. In such a case, the cell units 15 may be internally connected in series or parallel to each other in the casing 16 to adjust the module voltage to a desired voltage.

1. A solar cell module including at least one cell unit comprising a plurality of solar cells on a single substrate, each of said solar cells comprising a first electrode layer, a p-type light absorption layer, an n-type buffer layer, and a transparent second electrode layer which are successively disposed in the order named on the substrate in a direction away from the substrate, said solar cells being electrically connected in series to each other, wherein
said solar cells have a plurality of cell areas.

2. A solar cell module according to claim 1, wherein each of the solar cells disposed in end portions of said module has a greater cell area than a solar cell disposed in a central portion of said module.

3. A solar cell module according to claim 1, wherein said solar cells have identical longitudinal dimensions and different transverse dimensions, thereby providing different cell areas.
